(19) United States
(12) Patent Application Publication
(10) Pub. No.: US 2024/0413609 A1
(43) Pub. Date: Dec. 12, 2024

(54) PULSED OPTICAL SOURCE

(71) Applicant: University of Southampton, Southampton, Hampshire (GB)

(72) Inventors: Peter George Robin SMITH, Southampton, Hampshire (GB); Rex Hugh Seton BANNERMAN, Southampton, Hampshire (GB); Devin Hugh SMITH, Southampton, Hampshire (GB)

(73) Assignee: University of Southampton, Southampton, Hampshire (GB)

(21) Appl. No.: 18/697,112

(22) PCT Filed: Sep. 28, 2022
(86) PCT No.: PCT/GB2022/052451

§ 371 Date: Mar. 29, 2024

(30) Foreign Application Priority Data
Sep. 29, 2021 (GB) 2113945.6

(51) Int. Cl. H01S 5/14; H01S 3/067; H01S 3/094; H01S 3/0941; H01S 3/102; H01S 3/137; H01S 3/30

(52) U.S. Cl. CPC H01S 5/146; H01S 3/0675; H01S 3/094046; H01S 3/094053; H01S 3/094076; H01S 3/09415; H01S 3/1024; H01S 3/137; H01S 3/302

(57) ABSTRACT

An optical source comprises: a pump source operable to generate laser light at a first wavelength; a single mode optical fibre arranged to receive laser light at the first wavelength from the pump source, the optical fibre being fabricated from material having a Raman gain profile for stimulated Raman scattering of light at the first wavelength, and a Brillouin gain profile for stimulated Brillouin scattering of light at the second wavelength to a third wavelength longer than the second wavelength; and a superstructured fibre Bragg grating formed in the optical fibre, the grating comprising: a periodic refractive index profile along a core of the optical fibre, giving transmission of the first wavelength to allow received laser light at the first wavelength to enter the superstructured fibre Bragg grating, reflection of the second wavelength at a first level, and reflection of the third wavelength at a second level lower than the first level; and a phase shift at an intermediate location along a length of the grating; wherein the series of pulses at the third wavelength comprise a pulsed output of the optical source.

### BACKGROUND OF THE INVENTION

The present invention relates to pulsed optical sources.

Conventional lasers rely on the formation of a population inversion across an energy bandgap in a lasing gain medium, achieved by pumping the medium at a suitable energy to stimulate emission of an optical output at a wavelength defined by the energy levels of the population inversion. Available laser output wavelengths are hence limited by the energy level structures of suitable gain media, which often require particular dopant materials, and the ability to provide a matched pump. Tunability of the output also tends to be limited.

An attractive alternative is the Raman laser, in which the optical output is derived by stimulated Raman scattering of a pump optical input in a suitable Raman gain material, the Raman scattering being at a wavelength which is shifted from the pump wavelength to a lower energy (longer wavelength) by an amount that depends on the Raman properties of the material (Raman shift). Hence the output wavelength depends at least partly on the pump wavelength, and is freed from the constraints of a conventional lasing medium, so tunability is more easily achieved by changing the pump wavelength.

Raman lasers can be made from bulk material, but are more commonly formed in an optical fibre, with fibre Bragg gratings defining either end of a resonant cavity, since this provides several benefits. The small diameter of optical fibre gives tight confinement of the light and corresponding higher levels of Raman gain, and the output can have a single spatial mode, giving excellent optical beam quality. Silica, from which many optical fibres are fabricated, has a useful Raman gain and Raman shift. However, optical fibre Raman lasers are typically long (tens or hundreds of metres), because the Raman effect is weak with a low gain per unit length of fibre, so a lot of fibre is needed inside the cavity to achieve a significant output power. Pump thresholds are typically high, requiring at least one watt of pump power and often more. The long cavity length is able to support very many longitudinal modes, so output at a single wavelength is not possible. Hence, these Raman lasers have limited commercial and scientific use.

An alternative is to define the resonant cavity in the optical fibre using a superstructured fibre Bragg grating containing an appropriate phase shift [1, 2, 3, 4]. The grating forms the entirety of the cavity, and can be very much shorter than a regular fibre Raman cavity, typically just a few tens of centimeters. This is made possible because the energy transfer from the pump wavelength to the Raman wavelength is a nonlinear optical process and so depends on the intensity of the Raman light present in the fibre. When a strong resonant Raman lasing is established by the high reflectivity of a suitably designed superstructured fibre Bragg grating there is significant and useful energy transfer from the pump even in a single optical pass. The drawback of low Raman gain per unit length in optical fibre is overcome, and a long cavity is no longer required, replaced with a compact structure. The pump power threshold is also reduced, and high slope efficiencies can be achieved. The short cavity length supports a single resonant longitudinal mode only, extraneous longitudinal modes being suppressed, so a narrow linewidth single wavelength/frequency output is generated, suited to a host of applications.

Lasers based on the Raman effect in superstructured fibre Bragg gratings are therefore attractive, and developments in this field are of interest.

### SUMMARY OF THE INVENTION

Aspects and embodiments are set out in the appended claims.

According to a first aspect of certain embodiments described herein, there is provided an optical source comprising: a pump source operable to generate laser light at a first wavelength; a single mode optical fibre arranged to receive laser light at the first wavelength from the pump source, the optical fibre being fabricated from material having a Raman gain profile for stimulated Raman scattering of light at the first wavelength such that received laser light at the first wavelength experiences stimulated Raman scattering within the optical fibre to a second wavelength longer than the first wavelength, and a Brillouin gain profile for stimulated Brillouin scattering of light at the second wavelength to a third wavelength longer than the second wavelength; and a superstructured fibre Bragg grating formed in the optical fibre, the grating comprising: a periodic refractive index profile along a core of the optical fibre, giving transmission of the first wavelength to allow received laser light at the first wavelength to enter the superstructured fibre Bragg grating, reflection of the second wavelength at a first level, and reflection of the third wavelength at a second level lower than the first level; and a phase shift at an intermediate location along a length of the grating to create, via the reflection at the first level, a resonant cavity for the second wavelength that enables light at the second wavelength to reach an intracavity power sufficient for the stimulated Brillouin scattering to occur so that light at the second wavelength undergoes a wavelength shift to the third wavelength until the intracavity power at the second wavelength becomes insufficient for the stimulated Brillouin scattering to occur, the light at the third wavelength coupling out of the resonant cavity, via the reflection at the second level, as a series of pulses corresponding to the intracavity power at the second wavelength being sufficient for the stimulated Brillouin scattering to occur; wherein the series of pulses at the third wavelength comprise a pulsed output of the optical source.

According to a second aspect of certain embodiments described herein, there is provided a method for generating optical pulses, comprising: delivering pump laser light at a first wavelength into a resonant cavity, where the resonant cavity is formed in single mode optical fibre fabricated from material having a Raman gain profile for stimulated Raman scattering of the pump laser light at the first wavelength such that the delivered pump laser light at the first wavelength experiences stimulated Raman scattering within the optical fibre to a second wavelength longer than the first wavelength, and having a Brillouin gain profile for stimulated Brillouin scattering of light at the second wavelength to a third wavelength longer than the second wavelength; wherein the resonant cavity comprises a superstructured fibre Bragg grating comprising: a periodic refractive index profile along a core of the single mode optical fibre, giving transmission of the first wavelength to allow the pump laser light at the first wavelength to enter the superstructured fibre Bragg grating, reflection of the second wavelength at a first level, and reflection of the third wavelength at a second level lower than the first level; and a phase shift at an intermediate location along a length of the grating to create, via the reflection at the first level, the resonant cavity for resonance of the second wavelength that enables light at the second wavelength to reach an intracavity power sufficient for the stimulated Brillouin scattering to occur so that light at the second wavelength undergoes a wavelength shift to the third wavelength until the intracavity power at the second wavelength becomes insufficient for the stimulated Brillouin scattering to occur, the light at the third wavelength coupling out of the resonant cavity, via the reflection at the second level, as a series of pulses corresponding to the intracavity power at the second wavelength being sufficient for the stimulated Brillouin scattering to occur; and taking the series of pulses at the third wavelength as the generated optical pulses.

These and further aspects of certain embodiments are set out in the appended independent and dependent claims. It will be appreciated that features of the dependent claims may be combined with each other and features of the independent claims in combinations other than those explicitly set out in the claims. Furthermore, the approach described herein is not restricted to specific embodiments such as set out below, but includes and contemplates any appropriate combinations of features presented herein. For example, optical sources may be provided in accordance with approaches described herein which includes any one or more of the various features described below as appropriate.

### BRIEF DESCRIPTION OF THE DRAWINGS

For a better understanding of the invention and to show how the same may be carried into effect reference is now made by way of example to the accompanying drawings in which:

FIG. 1 shows a simplified schematic representation of an example of a pulsed optical source according to the present disclosure;

FIG. 2 shows a graphical representation of energy transfer processes utilised in pulsed optical sources according to the present disclosure;

FIG. 3 shows an image of an experimentally measured temporal trace of a pulsed output from an example optical source according to the present disclosure;

FIG. 4 shows an image of experimentally measured temporal traces of output pulses and residual pump light from an example optical source according to the present disclosure;

FIG. 5 shows a schematic representation of some example superstructured fibre Bragg grating (SSFBG) designs for use in pulsed optical sources according to the present disclosure;

FIG. 6 shows modelled graphical representations of a transmission spectrum and a reflection spectrum of an example SSFBG suitable for use in pulsed optical sources according to the present disclosure;

FIG. 7 shows an example transmission spectrum measured under experimental conditions from a SSFBG for use in a pulsed optical source according to the present disclosure;

FIG. 8 shows a modelled graphical representation of a Raman optical field within a SSFBG in an example pulsed optical source according to the present disclosure;

FIG. 9 shows a graph of Raman spectra of various oxide glasses [5];

FIG. 10 shows a schematic representation of another example pulsed optical source according to the present disclosure;

FIG. 11 shows a schematic representation of a further example pulsed optical source according to the present disclosure;

FIG. 12 shows a schematic representation of a yet further example pulsed optical source according to the present disclosure; and

FIG. 13 shows a schematic representation of an example SSFBG for use in a pulsed optical source according to a further example of the present disclosure.

### DETAILED DESCRIPTION

Aspects and features of certain examples and embodiments are discussed/described herein. Some aspects and features of certain examples and embodiments may be implemented conventionally and these are not discussed/described in detail in the interests of brevity. It will thus be appreciated that aspects and features of optical sources and methods of operating such sources discussed herein which are not described in detail may be implemented in accordance with any conventional techniques for implementing such aspects and features.

Many nonlinear optical effects can occur in an optical fibre in addition to the stimulated Raman scattering which is utilised as optical gain to provide amplification in a Raman laser such as a superstructured fibre Bragg grating (SSFBG) Raman laser. One effect, which is related to the Raman effect, is stimulated Brillouin scattering (SBS). In common with Raman scattering, Brillouin scattering shifts input light to a longer wavelength, but typically by a much smaller amount. As an example, in silica the Brillouin shift is about 11-13 GHZ (around 0.05 nm), compared to the much greater shift of up to 16 THz (or many tens of nanometres) provided by Raman shifting. The mechanism of SBS is input light, at a power level above a threshold for producing SBS, interacting with an acoustic wave in the glass of the fibre, which creates a travelling Bragg grating through electrostriction. Scattering from this grating produces a frequency shifted, typically backwardly propagating, optical wave. Over long distances of optical fibre, such as in a conventional Raman laser, the presence of SBS can substantially limit the transmissible power, which needs to be kept below the SBS threshold to avoid losses to the Brillouin shifted wavelength. Note that the concept of a threshold for SBS, and also for Raman scattering, can be an imprecise characteristic, dependent on varying factors and consequently difficult to define, although well understood to be a real effect. For a particular system or arrangement, power at the originating or pump wavelength needs to reach a sufficient level for Brillouin (or Raman) scattering to occur, but there are various ways to quantify or define such a threshold level. This is because Raman and Brillouin scattering are gain phenomena; this is particularly true if there is not a strongly defined resonant cavity for the particular scattering (which is true of the Brillouin scattering effect utilised in the present invention and described further below). This can be contrasted with the more straightforward and quantifiable concept of a threshold for lasing via a population inversion. For Raman and Brillouin scattering, definitions of a “threshold” at or above which the scattering is considered to be taking place are varied, examples including requiring a certain amount of gain at the Raman or Brillouin wavelength to be present, such as 90 dB, or requiring that the power or energy at the Raman or Brillouin wavelength becomes comparable to that of the pump light which undergoes the scattering. The length of the fibre is also pertinent. In telecommunications systems, a threshold or critical power can be derived based on the extremely long length of optical fibre being limited by a characteristic optical loss, giving the idea of launching optical power into an infinitely long fibre which has an effective length given by the inverse of the loss. This is less applicable in the present case since only short optical fibre lengths are used for SSFBG Raman lasers. Consequently, while the term “threshold” for Raman and Brillouin scattering may be used herein for convenience and will be appreciated by the skilled person to refer to a widely understood concept, precise values of power at or above which these effects can be considered to be occurring are difficult to quantify.

The present invention proposes to make use of SBS in a Raman laser, however, and provides a simple device structure which is operable as a source of optical pulses. Previous SSFBG Raman lasers typically operate in a continuous wave regime. A pulsed laser output has numerous advantages. Higher peak powers are exhibited, particularly for nanosecond, picosecond and femtosecond pulse durations. These are useful for applications such as material processing and medical treatments, where the delivery of high peak power at a lower average power can reduce damage from heating. In the field of nonlinear optics, high peak powers offer access to frequency conversion processes such as second harmonic generation, sum frequency generation, difference frequency generation and optical parametric generation.

Conventionally, a pulsed laser is more structurally complex than a continuous wave laser, because dedicated elements are required to create the pulsing behaviour. These include passive elements such as saturable absorbers and active elements such as acousto-optic or electro-optic Q-switches, any of which tend to make such lasers costly. Also, the output is often quite spectrally broad, particularly in the nanosecond regime.

In contrast, the optical source proposed herein can generate a pulsed output of nanosecond duration pulses of laser light having an extremely narrow linewidth optical spectrum, and without any additional pulse-forming structural elements.

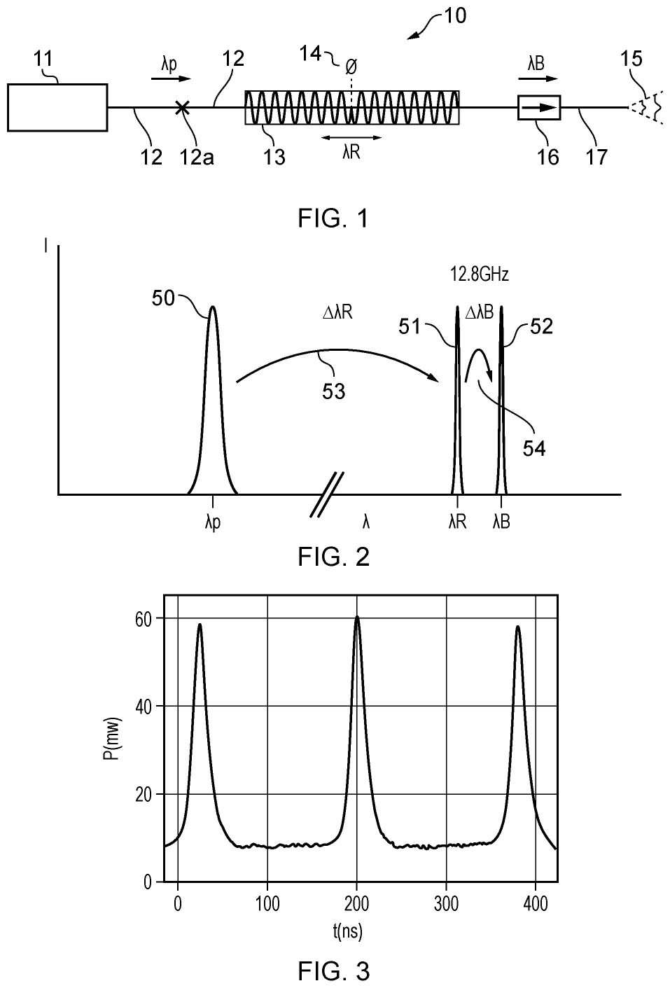

FIG. 1 shows a simplified schematic diagram of an example of an optical source according to the present disclosure. The optical source 10 comprises a pump source 11 operable to generate an optical output comprising laser light at a first, pump, wavelength λp. In this example, and in general for simpler implementations, the pump source generates continuous wave pump light. The optical source 10 is based on optical fibre, so for convenience the pump light may have a beam format suitable for effective coupling into a single mode optical fibre. In this example, the pump source 11 has an output optical fibre which is coupled at a connection 12a to an optical fibre 12. The connection 12a may comprise a physical fibre connector, or be achieved by splicing such as with a fusion splicer. Splicing may be preferred as providing a more robust join and better optical power handling, spliced connections being able to accommodate higher powers than terminated fibre connectors.

The resonant cavity of the pulsed laser optical source 10 is provided by a superstructured fibre Bragg grating (SSFBG) 13, which is created within the core of a suitable single mode optical fibre. This may be the fibre 12 which couples to the pump source 11, or may be separate portion of optical fibre which is coupled to the fibre 12. A fibre Bragg grating (FBG) is a series of periodic differences in effective refractive index periodic refractive index profile arranged along the length of an optical fibre core, and hence along the direction of light propagation along the core. The effect of the grating is to cause reflection of incident light at a wavelength or wavelengths within the spectral response of the grating, which is defined by the period of the refractive index changes in the grating. The amount of reflection which occurs, referred to as the strength of the grating, is controlled by the size of the refractive index changes and the length of the grating (how many refractive index changes it includes). Hence, an FBG can be fabricated so as to have a particular reflective effect in terms of both wavelength and strength.

A SSFBG is more complex, and additionally includes a phase shift 14 at a chosen location intermediate along its length, indicated as Φ in FIG. 1. This allows the single SSFBG 13 to form a resonant cavity able to reflect light back and forth within its own length. The phase shift 14 may be a π phase shift as shown in FIG. 1, or a phase shift close to π such as in the range of 75% to 100% of π, although smaller values may be used, for example the phase shift may be in the range of 50% to 100% of π, equivalently between π/2 and π inclusive [6]. Phase shifts of less than π can be used to compensate for thermal effects, for example. Also, FIG. 1 shows the SSFBG 13 as a simple uniformly structured grating with the phase shift 14 placed at its centre or midpoint (halfway along the length of the grating). In other examples, however, the phase shift 14 may be displaced from the central position, so as to be closer to one end of the grating than the other. This can enhance uni-directional output from the resonant cavity (compared to equal output from both ends), and also correct for nonlinearities that may occur. For example, the phase shift may be located up to 25% of the grating length away from the grating centre, in other words, in the range of 0% to 25% inclusive of the total grating length from the central position of the grating.

Significantly, however, the spectral response of the SSFBG 13 is particularly designed in order to enable the required pulsed output. Firstly, the SSFBG 13 is structured to allow transmission (low reflective response) of light at the pump wavelength λp, in order for pump light arriving along the optical fibre 12 to enter, and pass through, the resonant cavity.

Secondly, the SSFBG 13 is structured to have a very strong or high reflective response at a second wavelength different from the first, pump, wavelength. This second wavelength, which we may define as being the central wavelength of the reflectivity response or profile of the SSFBG 13, is chosen to be within the Raman gain profile provided by the material of the optical fibre in which the SSFBG 13 is formed, for light at the pump wavelength λp. In other words, pump light coupled into and propagating through the SSFBG 13 which experiences stimulated Raman scattering in the material of the optical fibre, and is hence shifted to a Raman wavelength λR, is highly reflected back and forth within the SSFBG 13. This reflection allows the creation of an intense resonated wave at the Raman wavelength. Hence, the SSFBG 13 is designed having regard to the pump wavelength λp and the material of the optical fibre so as to be reflective at a first, high, level for a wavelength matching the Raman wavelength to which light at the pump wavelength λp is shifted by the Raman scattering response of the particular material chosen for the fibre.

The SSFBG 13 is designed with a high reflective strength such that it provides an exceptionally high Q factor (quality factor) for light at the Raman wavelength λR, in order to allow the build-up, over time as more pump light is delivered into the cavity and undergoes Raman scattering, of a high optical intensity of the Raman wavelength light within the cavity of the SSFBG 13. A high Q factor in an optical resonator arises from a low fractional loss of optical power per round trip through the cavity, so can be achieved by high reflectivity. As is well-understood, a high Q factor corresponds to a high cavity finesse. Useful values of finesse in the present case are 250 or above, for example in the range of about 250 to 100,000, for example around 25,000, or between 20,000 and 30,000, or between 15,000 and 35,000, or between 10,000 and 40,000.

In a conventional SSFBG Raman laser, the reflectivity at the Raman wavelength λR will be tailored at a lower level to provide output coupling from the laser, such that a fraction of the circulating light is able to escape from the cavity. In the present case, however, the aim is to maximise the peak optical power at the Raman wavelength λR within the cavity, so the output coupling at this wavelength is removed/minimised by very high reflectivity in the SSFBG. A longer grating can reduce output coupling at the Raman wavelength. Examples of useful grating lengths are in the range of about 100 mm to 500 mm, although longer and shorter gratings are not excluded. The purpose of this power accumulation is to enable the intracavity peak power of the light at the Raman wavelength to reach the threshold for SBS in the material of the optical fibre in which the SSFBG is defined.

Once the Raman wavelength power is sufficient for SBS to occur, in other words, the SBS threshold is reached or exceeded, the circulating optical power at the Raman wavelength undergoes Brillouin scattering, and there is a rapid transfer of energy from the Raman wavelength to the wavelength at the peak of the Brillouin gain. The light at this further shifted wavelength is intended as the output of the optical source 10.

In order to obtain this output, the SSFBG is thirdly structured to be at least partially transmissive (in other words to provide a low or zero reflectivity or be only partially reflective) at a third wavelength, which is the wavelength to which light at the Raman wavelength λR is shifted when it undergoes SBS, which we may refer to as the Brillouin wavelength λB. This transmissivity at λB, being reflectivity at a second level, lower than the reflectivity at the first level for the Raman wavelength, provides the output coupling for the optical system. The reflectivity at the first level may be at least 20 dB greater or higher than the reflectivity at the second level, for example 20 dB greater, 30 dB greater, 40 dB greater or 50 dB greater, although intermediate and larger differences in reflectivity at the two levels are not excluded, and pulsed operation may also be achievable for reflectivity differences less than 20 dB. Hence, the output of the optical system is at the pump wavelength λp plus the Raman shift which we can designate at ΔλR plus the Brillouin shift which we can designate at ΔλB. The Brillouin shifted light is able to rapidly escape from the cavity.

The pulsed character of the output at the Brillouin wavelength λB arises because the scattering of the light at the Raman wavelength λR ceases when the intra-cavity peak power drops below the SBS threshold (owing to the transfer of energy via the Brillouin shift), and output at the Brillouin wavelength λB also ceases. Continued pumping with the pump light allows the Raman light to then build up again to the SBS threshold, allowing another rapid shift to the Brillouin wavelength λB, emitted as a further pulse. This process repeats to generate a series or stream of pulses as the output of the optical source. Appropriate tailoring of the structure of the SSFBG and selection of the level of power of the incoming pump light can modify the duration of the Raman build up and the Brillouin scattering and hence set the pulse duration and the pulse repetition rate, but overall physical limitations tend to best enable pulses of nanoseconds duration.

Hence, the optical source 10 exhibits self-pulsing behaviour (pulse generation without the need for any dedicated pulse-forming elements), and a pulsed optical output is enabled from a very simple laser structure.

FIG. 1 also shows an optical isolator 16, for example based on the Faraday effect, along an output fibre 17 from the SSFBG 13, which acts to prevent or inhibit retro-reflection back into the cavity. This is especially important for any escaped light at the Raman wavelength because even small reflections here can significantly alter the spectral response of the SSFBG. The output beam 15 from the optical source 10 exits the output fibre 17, and can be emitted into free space as shown, or may be coupled into another optical fibre, as required. A filtering element (not shown) may also be included to remove or divert transmitted pump light from the pulsed optical output 15.

FIG. 2 shows a graphical representation of the energy transfer processes that produce the wavelengths shifts in the optical source, as a spectrum of the relevant optical waves shown as intensity I (normalised) against wavelength λ. The peak 50 at the shortest wavelength is the input pump light at the pump wavelength λp. The energy at this wavelength is transferred via stimulated Raman scattering to a peak 51 at the longer, Raman wavelength λR. Then, the energy at this wavelength is in turn transferred via stimulated Brillouin scattering to a peak 52 at the still longer, Brillouin wavelength λB. The arrow 53 indicates the Raman wavelength shift ΔλR. This shift is many tens of nanometres in size. For example, Raman scattering in a silica fibre can shift pump light at 1064 nm to Raman light at 1120 nm. The smaller arrow 54 indicates the Brillouin wavelength shift ΔλB, which is much smaller, typically around 12 or 13 GHZ (less than one-tenth of a nanometre) in silica. Note the discontinuity within the wavelength axis to indicate the relative sizes of the shifts.

The peak 50 at the pump wavelength λp is spectrally broader than both the Raman peak 51 and the Brillouin peak 52. A useful characteristic of the proposed optical source is that the output light can be significantly spectrally narrower than the pump light. The pump source can produce multiple longitudinal modes (broadband), but the SSFBG cavity structure ensures that the Raman and Brillouin light are narrow line.

FIG. 3 shows an image of a temporal trace of a pulsed output from an optical source configured in line with FIG. 1, detected with a photodiode for display on an oscilloscope. The trace shows forward lasing power in mW (in other words, the power of the output beam 15 in FIG. 1) against time in ns. Three pulses are shown, of duration (at full width half maximum) about 15 ns. A non-zero background power “pedestal” can be seen between the pulses, presumed to be residual output at the Raman wavelength (the SSFBG not providing 100% intra-cavity reflection for the circulating light). The shape of the pulses, smooth and slightly asymmetrical with a steeper rise and slower decay, is typical of pulses generated by the known technique of Q-switching. This method of pulse generation actively modulates the Q-factor of a cavity in a conventional laser by periodically increasing the loss to allow the output coupling of optical energy stored in the gain medium by a population inversion. In contrast, the proposed optical source stores optical energy in the cavity as the resonant Raman light, and provides a reduced Q-factor for output coupling by shifting the stored energy to a different (longer) wavelength for which the cavity Q-factor is less high. Other measurements have shown other behaviour similar to a Q-switched output, and in line with the mechanism of periodic wavelength shifting described above. An increase in pump power input into the cavity increases the peak power of the output pulses in a linearly proportional manner. Increasing the pump power also reduces the pulse-to-pulse period (higher pulse repetition rate), as expected because the circulating Raman light can reach the SBS threshold more quickly after being reduced by each output pulse.

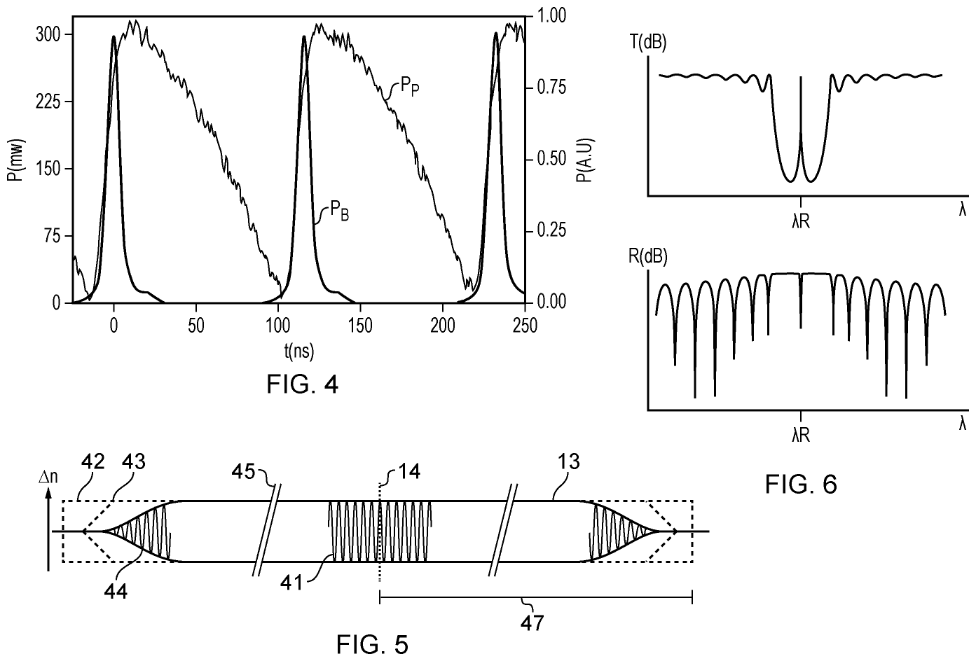

FIG. 4 shows an image of measured temporal traces of output pulses (left hand axis, forward lasing power in mW) compared with the pump light (right hand axis, measured in parallel with the output pulses from residual power escaped from the cavity, and with an AC-coupled detector, and hence in arbitrary units). This shows how the pump power, Pp is depleted over time as the pump energy is shifted to the Raman wavelength in the cavity, followed by a sharp rise as soon as a pulse PB begins, recovering to the maximum input power level as the pulse finishes, ready for the next depletion.

FIG. 5 shows a schematic representation of example SSFBG designs. The refractive index difference Δn (the periodic index change or modulation that provides the grating's reflective properties) in the SSFBG 13 is indicated as a cosinusoidal variation 41a with spatial position along the length of the grating. The period ∧ of the grating, in other words, the period of the index variation, is related to the reflected wavelength λ_{Bragg} by the formula λ_{Bragg}=2 nₑ∧ where nₑ is the effective refractive index of the grating in the optical fibre core.

Various possible envelopes for the grating modulation are included. A first design 42 is a grating with a square profile, in which the index modulation begins abruptly. Second and third designs 43, 44 employ differing amounts of apodisation, in which the grating strength is gradually increased from zero over a portion at the start of the grating and decreased to zero over a portion at the end of the grating. Apodisation is equivalent to slowly “switching” the grating on and off and is a known feature of FBGs. The apodisation can follow a Gaussian profile, for example, but other shapes are possible. It may be included to tailor the reflectivity and hence output coupling at the Brillouin wavelength and/or to improve absorption of the incident pump light.

The grating design for the SSFBG 13 should take account of a number of factors. The grating contrast (maximum Δn) may be deliberately ‘weak’ so that the optical mode extends along a substantial fraction of the SSFBG length. The grating is may also be designed to be “long” so that a very high reflectivity can be achieved. FIG. 5 shows two discontinuities 45 in the grating length to represent that the overall structure of the SSFBG 13 might usefully have a length in the range 20-30 cm (other lengths are possible however), while the grating periods will be sub-micrometre.

The grating fringes may be formed in the fibre core by any known FBG fabrication process. An example is a two beam laser writing method in which two beams from the same continuous wave ultraviolet laser are brought to a common focus to form an interferometric pattern matching the desired grating design, to which the fibre core is exposed, the ultraviolet radiation causing a refractive index change. Phase modulation via a computer-controlled electro-optic modulator is applied in one beam to set the interferometric pattern. Other methods include the use of phase masks to apply the ultraviolet light. A high degree of phase accuracy is desirable in order to achieve a grating with a very narrow spectral resonance.

The phase shift 14 in the grating acts to create a phase difference of π or near −π. FIG. 5 shows the phase shift in the centre of the SSFBG 13, although the spacing 47 of the phase shift 14 from the end of the grating may be changed from this midpoint. Placing the phase shift 14 towards one end of the grating (the spacing 47 thereby being less than or more than half the total grating length) can help to increase unidirectionality in the laser output, and coupling efficiency.

FIG. 6 shows graphical representations (obtained by modelling) of a transmission spectrum and a reflection spectrum of an example SSFBG suitable for use in the proposed pulsed optical source. Note that the scale on the graphs is logarithmic (transmission T and reflection R in decibels dB). It can be seen that there is a wider central feature of high transmission and low reflection, in the centre of which there is a narrow spectral feature of low transmission and high reflection, at the Raman wavelength λR. This very high Q-factor resonance is very narrow, of the order of femtometres. So, extremely high reflectivity is provided to allow pump light which has been shifted to the Raman wavelength λR to build up, while the subsequent shift to the Brillouin wavelength λB allows the light to escape from the cavity because there is high transmission (lower reflectivity) for that wavelength. Even though the Brillouin shift is small, the narrowness of the reflection peak means that the shift take the light outside of the high reflection region.

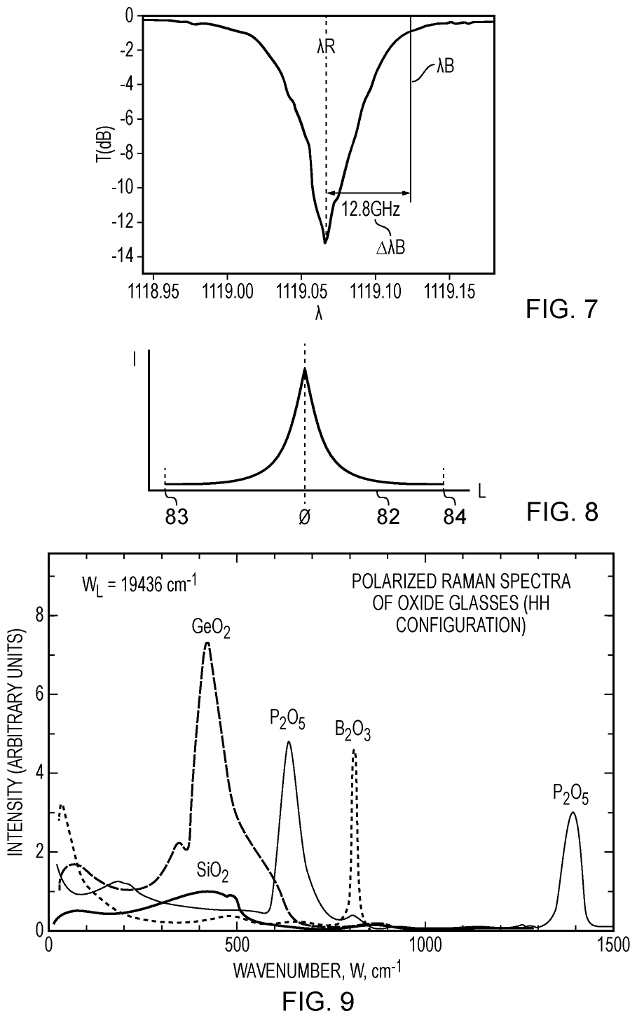

FIG. 7 shows an example transmission spectrum measured under experimental conditions from a real SSFBG formed in silica and used in an optical source as described herein. The measured transmitted signal strength T (dB) is shown as a function of wavelength (nm). Measurement was limited by the spectral resolution of the optical spectrum analyser used to measure the spectrum, which was unable to resolve the fine details of the resonant structure of the SSFBG caused by the π phase shift, and shown schematically in FIG. 6. The characteristic stop band dip is clearly shown, but the narrow central resonance feature at the Raman wavelength λR which creates the resonant cavity is not resolved.

Also shown is the intended position of the Brillouin wavelength λB, which in silica is shifted from the Raman wavelength λR by a shift ΔλB of about 12.8 GHz. The grating is designed so that a useful level of transmission is provided at the Brillouin wavelength to enable output coupling. The transmission level depends on the grating strength (which should be weak) and the grating length. If the grating is too strong, or too short, the transmission dip will broaden and the Brillouin-shifted light will be experience poor transmission and be unable to couple out of the SSFBG cavity.

As an example, the SSFBG from which the transmission spectrum was measured was 250 mm in length with a centrally located π phase shift. The grating was written using ultraviolet (244n nm) writing beams of 6 μm diameter, into a silica fibre.

FIG. 8 shows a schematic graphical representation of the Raman optical field within a SSFBG, as a plot of optical intensity I against spatial position along the length L of the grating. Hence, the spatial intensity distribution of the optical field along the SSFBG is shown. In practice the optical field is a standing wavefield so is spatially modulated with a period equal to half the wavelength, but for simplicity this is not shown in FIG. 8. Overall, the field comprises two exponential intensity distributions centred on the central phase shift Φ and decaying to zero or near zero at either end of the grating. This indicates that very little power is present at the ends of the grating, so that very little optical power at the Raman wavelength escapes. Instead the Brillouin shifted light is able to escape from the grating, hence the Brillouin output is a major means of output coupling the cavity.

The SSFBG can be formed in silica fibre, since silica demonstrates Raman and Brillouin scattering. However, in order to enhance the Raman gain and the Brillouin gain, it is possible to use optical fibre which is doped with one or more materials with a higher Raman and Brillouin response. A particular example is silica fibre doped with germanium.

FIG. 9 shows a graph of Raman spectra of various oxide glasses, taken from [5]. Note the broad flat peak of silica (silicon oxide SiO₂) with a fairly low intensity, and the very much higher peak for germanium oxide GeO₂ at similar wavelengths. Accordingly, an optical fibre formed from silica doped with germanium shows improved stimulated Raman and Brillouin scattering effects. Other dopants may be used to enhance the scattering; these include but are not limited to phosphorus, boron (also shown in their oxide forms in FIG. 9), bismuth, aluminium and fluorine.

It has been found to be useful for the SSFBG to be formed in optical fibre having a relatively small core diameter. This can concentrate the resonating optical energy to a higher intensity, enabling the peak power of the Raman light to reach the SBS threshold more easily. The core diameter may be in the range of about 1.5 μm to 10 μm, for example, although smaller or larger cores are not excluded.

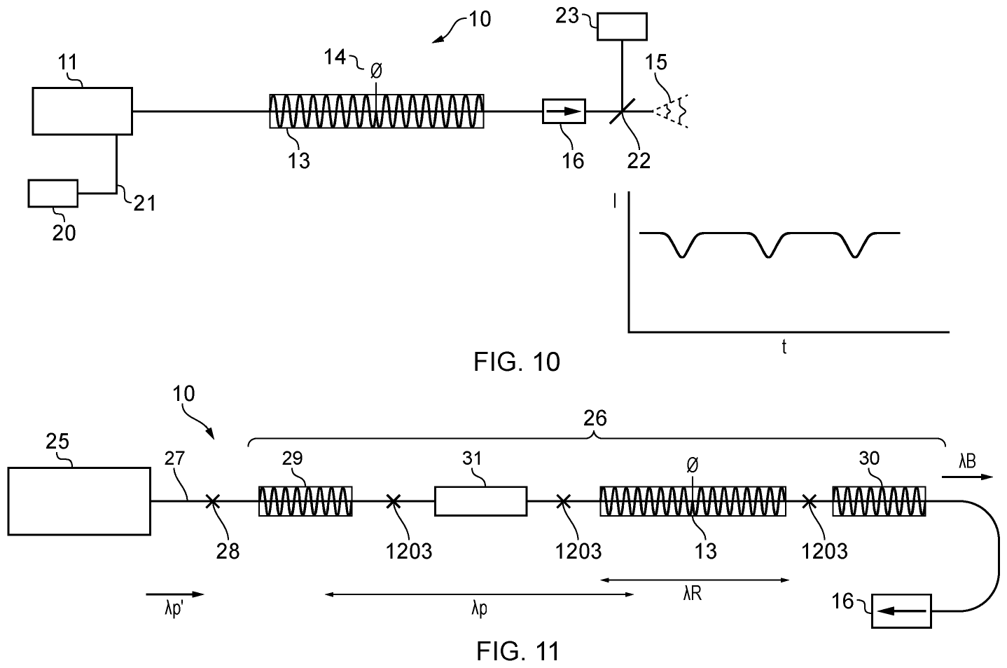

FIG. 10 shows a schematic representation of another example pulsed optical source. This example differs from the FIG. 1 example primarily in that the pump source 11 is itself a pulsed optical source, rather than the continuous wave source of FIG. 1. The pump source 11 comprises a laser diode, which is provided with control signals 21 from a pulse generator and electrical diode laser drive unit 20, which operate together in a conventional manner in order to modulate the continuous wave output of the laser diode 11 in order to create pulses of pump light. The inset graph shows the pump light power or intensity I over time t, from which it can be seen that the level of modulation need not be very large, for example to decrease the pump power down to 80% or 85% or 90% of its unmodulated level. It is sufficient merely to cause a small drop or decrease in the power level at periodic intervals (compared with full pulsed operation where the power level between pulses is effectively zero, for example), where this produces a corresponding drop in the pump power below the threshold for the Raman scattering on the SSFBG. The ability to use a shallow modulation depth only can simplify the cost and complexity of the pulse generator and electrical drive unit 20. It has been found that this can help to stabilise the self-pulsing behaviour of the SFBG optical source, by driving it into oscillation at the desired pulse repetition rate. Stable oscillation behaviour is produced, to give an output 15 at the Brillouin wavelength with a pulse repetition rate matching the modulation or pulse rate of the pump light. Other pulsed pump sources may be used in place of the described modulated laser diode. The system may optionally also include a beam splitter 22 to extract a small portion of the optical output 15 and direct it to an optical detector 23. The response of the detector 23 can be monitored to ensure that the required pulsed operation is being successfully achieved. It might also be used to determine or control operating parameters of the pulse generator, such as by a feedback arrangement to adjust the operating parameters if the pulsed output is found to be sub-optimal.

FIG. 11 shows a schematic representation of a further example pulsed optical source, which again differs from the FIG. 1 example by the configuration of the pump source. The examples of FIGS. 1 and 10 employ a pump source located externally and separately from the SSFBG resonant cavity, so that the pump light experiences only a single pass through the cavity. The embodiment of FIG. 11 instead places the SSFBG inside a pump resonant cavity or pump light cavity that amplifies and resonates the pump wavelength. Hence, the pump light passes multiple times through the SSFBG and the pumping efficiency of the Raman scattering process is enhanced.

The optical source 10 comprises as its pump source a semiconductor laser diode pump module 25 (other types of laser could be used alternatively) that generates an output at an initial pumping wavelength λp′ which is coupled into a single mode optical fibre 27, in order to be delivered into a pump light cavity 26 formed in optical fibre. The single mode fibre 27 is coupled to the pump light cavity 26 at a join 28 (a splice or other fibre connection). The pump light cavity 26 comprises a first fibre Bragg grating 29 and a second fibre Bragg grating 30 each formed in sections of optical fibre, arranged on either side of a portion of optical fibre 31 that has optical gain characteristics (gain fibre). The fibre Bragg gratings 29, 30 are configured to have high reflectivity at a lasing wavelength of the gain fibre 31, which is used as the pump wavelength λp for the Raman scattering. Hence, a resonant cavity is formed around the gain fibre 31. The pump module 25 is selected such that the initial pumping wavelength λp′ is suitable for pumping the gain of the gain fibre 31. The pump source providing the pump wavelength λp is hence configured as a fibre laser, and the pump light circulates around the pump light cavity 26. The gain fibre may comprise any know optical fibre with lasing properties, for example fibre doped with a rare earth element. An example is erbium-doped optical fibre, which can be driven by a pump module emitting an initial pumping wavelength λp′ of about 976 nm. Other example dopants include neodymium, ytterbium and holmium.

The SSFBG 13 is placed inside the cavity of the fibre laser pump source, between the gain fibre 31 and one of the fibre Bragg gratings 29, 30. The various portions of fibre in which the various elements are formed are coupled together, such as by fusion splicing, indicated in FIG. 11 by crosses. The SSFBG 13 is configured as already described, to generate pulses at the Brillouin wavelength λB, shifted from light at the Raman wavelength λR produced by stimulated Raman scattering of the pump light λp in the material of the SSFBG 13. One or both of the fibre Bragg gratings 29, 30 has good transmission at the Brillouin wavelength λB in order for the Brillouin light to escape from the pump light cavity 26 after it is emitted from the SSFBG. An optical isolator 16 can be included as discussed with regard to FIG. 1.

Incorporation of the SSFBG laser inside the cavity of the pump laser in this way gives effective absorption of the pump light before conversion to longer wavelength pulsed operation via the two stages of stimulated scattering. By suitable coupling of the initial pumping wavelength λp′ from the pump module 25 into the fibres of the pump light cavity, the gain fibre 31 may be core-pumped, or alternatively a cladding pumping scheme can be used; this is a common arrangement for pumping fibre lasers. A benefit of cladding pumping is that a spatially multimode laser diode can be used for pumping. Lasers of this sort are readily available commercially, so the embodiment of FIG. 11 offers the ability to take the inherently spectrally broad and spatially multimode output of an inexpensive commercial multimode laser and convert it into the Brillouin output which has a single spatial mode only and is spectrally brighter. The fibre laser pump source will inherently have multiple longitudinal modes formed between the fibre Bragg gratings, but the pulsed Brillouin output is nevertheless spectrally narrow.

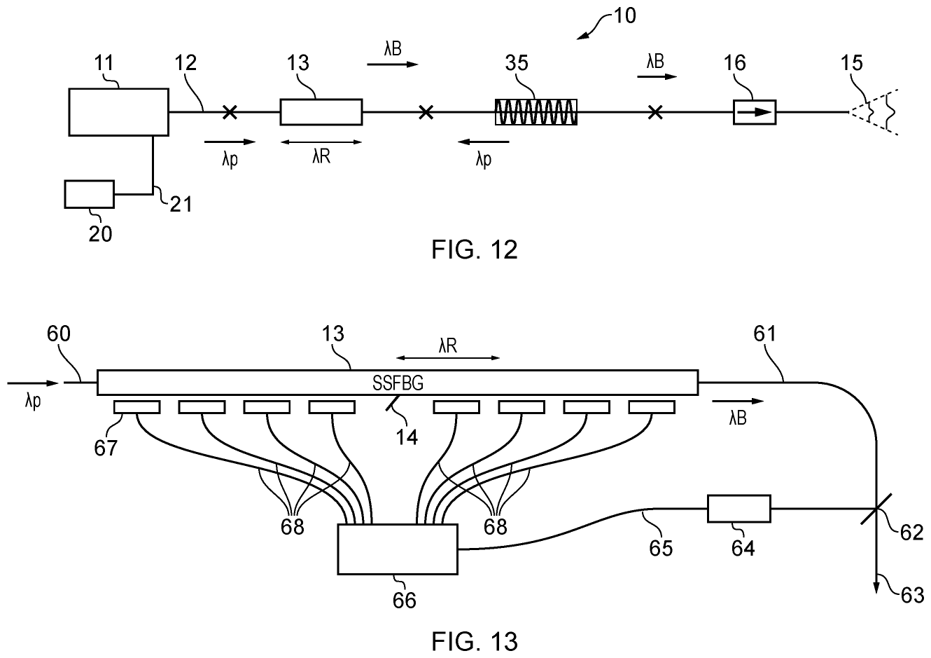

FIG. 12 shows a schematic representation of another example pulsed optical source, which provides enhanced utilisation of a commercial diode laser in an alternative way to the FIG. 11 example. As noted above, the output of semiconductor diode lasers (especially simple Fabry-Perot-based devices) tends to be spectrally broad, and may be somewhat unstable in lasing operation. This performance can be improved by the use of a fibre Bragg grating to provide stabilisation. For example, this is commonly employed for 976 nm diode lasers used to pump erbium doped fibre amplifiers, widely used in optical telecommunications systems.

In FIG. 12, the pump source 11 of the optical source 10 is configured in this way. The pump source 11 comprises a semiconductor diode laser (with an electrical drive unit 20) having an output optical fibre 12 as before, but additionally a fibre Bragg stabilisation grating 35 is included, separated from the pump source 11 and located about 1 m along the output fibre 12 (this is a conventional spacing for grating stabilisation of diode lasers, but the invention is not limited in this regard; other spacings may be used). The grating 35 has some reflectivity at the pump wavelength λp from the pump source 11, so provides optical feedback which acts to stabilise the operation of the diode laser pump source 11.

Additionally, the SSFBG 13 is located between the pump source 11 and the stabilisation grating 35, within the typically 1 m separation between these components. The SSFBG 13 is depicted as being formed in a separate portion of fibre which is spliced or otherwise coupled between the stabilisation grating 35 and the initial part of the output fibre 12. Alternatively, the SSFBG 13 and the stabilisation grating 35 can be written into the same length of optical fibre, which could be coupled directly to the pump source 11 as the output fibre 12. As in previous examples, an optical isolator 16 is included, located after the stabilisation grating 35. The stabilisation grating 35 has good transmission at the Brillouin wavelength λB to deliver the optical source pulsed output 15. The electrical drive unit 20 can be operated such that the pump source is continuous wave, or emits pulses which can be used to set a desired pulse repetition rate for the Brillouin output as described with regard to FIG. 10.

This configuration allows readily commercially available inexpensive stabilised laser diodes to be easily adapted into a pulsed optical source, simply by providing a SSFBG along the output optical fibre.

Further regarding the configuration of the pump source, the proposed optical source is well-suited to providing a desired polarisation of the emitted pulses at the Brillouin wavelength. The relatively short length of the SSFBG allows the pump light to maintain its input polarisation state over the cavity length, and the nature of the Raman and Brillouin processes ensures preferential transfer of energy into the same polarisation state. Hence, the polarisation of the pump light can be set as desired in order to produce the same polarisation in the output pulses. This can be achieved in any convenient manner, such as the inclusion of a polarising element between the pump source and the SSFBG.

The examples described above have utilised a single Raman shift of the input pump light to drive the Brillouin shift and obtain the output pulses. However, the SSFBG can be configured, by tailoring of the grating fringes, to utilise multiple (two or more) Raman shifts between the pump light and the Brillouin shift. The Raman shifts can be cascaded in order to move the final output wavelength of the optical source further from the pump wavelength, thereby enabling access to a wider range of pulsed output wavelengths. Operation of the optical source is that pump light shifted to the Raman wavelength λR by the Raman shift ΔλR itself undergoes Raman scattering to experience a further Raman shift ΔλR to a second Raman wavelength λR′, and so on if further shifts are required to a third Raman wavelength λR″ or further, with the final longest Raman wavelength undergoing SBS to the Brillouin wavelength which is coupled out of the SSFBG cavity in pulses as already described. In order to achieve this, the SSFBG is structured to additionally have a high reflectivity (high Q-factor, high finesse) at each of the additional Raman wavelengths, so that each is able to resonate in the SSFBG cavity. So, the SSFBG has high reflectivity at λR, at λR+ΔλR, at λR+2ΔλR . . . and at λR+NΔλR, and low reflectivity for output coupling at λR+NΔλR+ΔλB. Note that this nomenclature is for ease of understanding following on from the preceding description. In reality, the multiple Raman shifts are of a constant size in the frequency or energy domain rather than in the wavelength domain, so that each successive λR is not the same size as the previous one, with the difference becoming more pronounced as the number of shifts increases. A SSFBG with multiple resonant wavelengths can be utilised with any of the various optical source configurations described herein.

FIG. 13 shows a schematic representation of an example SSFBG for use in a pulsed optical source according to a further example. An SSFBG configured according to this example may be utilised with any of the various optical source configurations described herein. The SSFBG 13 is written into optical fibre with a fringe configuration to provide the required reflectivity properties and resonance(s) at the Raman wavelength(s) λR as already discussed. Pump light at the pump wavelength λp enters the cavity of the SSFBG 13 via an input fibre 60, and out-coupled pulses at the Brillouin wavelength λB are taken from the SSFBG 13 via an output fibre 61, where the input and output fibres 60, 61 couple the SSFBG into the remaining elements of the optical source (not shown) as previously described. In this example, however, a beam splitter 62 is located along the output fibre 61 in order to separate a fraction of output light from the main laser output path. The beam splitter may be an all-fibre device, or could utilise bulk optical components such as beam splitter cubes or dielectric elements. The separated fraction of the output light is directed by the beam splitter to an optical detector 64 configured to detect and resolve the individual pulses in the output. Hence, for example, it may comprise a sufficiently fast photodiode detector able to resolve the nanosecond pulses directly, such as a biased photodiode used with an analogue-to-digital converter, or a second harmonic crystal arranged as an autocorrelator with a filter to remove the original Brillouin wavelength and a slow detector. The detector generates an electrical output signal 65 representing the temporal characteristics of the output pulses from the optical source, and this is supplied to a controller such as a microcontroller 66.

A number of separate and individual electrically operated actuators 67 are associated with the SSFBG 13. The actuators 67 are distributed along the length of the SSFBG 13, and configured to act on the material of the SSFBG 13 so as to independently and locally perturb or modify the properties of the SSFBG in order to change the reflectivity/transmissivity characteristics. Typically the actuators will be physically coupled to the exterior of the SSFBG fibre, but may be separated from it via a substrate supporting the fibre and/or the actuators, for example. The microcontroller 66 includes a processor which is configured to assess the characteristics of the electrical signal 65 to determine if adjustment of the pulsed output is required (to achieve a desired optimum or a particular operation, for example), and to cause the microcontroller to supply individual control signals 68 to one or more of the actuators to modify the SSFBG characteristics such as to move the pulsed output to or towards the desired operation. Different control signals sent to different actuators can tailor the perturbation along the length of the SSFBG 13 to dynamically reshape the grating.

The actuators 67, which for any SSFBG may be all of the same type, may comprise, for example, heating elements configured to deliver heat energy to the SSFBG material. This can alter the grating by causing thermal expansion so that the fringe period is altered, and/or by causing a thermally-induced refractive index change (since for some materials refractive index has a temperature-dependence). Alternatively, the actuators 67 may be piezo-electric elements physically coupled to the SSFBG fibre and configured to change dimension when an electrical signal is applied, thereby causing local strain in the SSFBG, again changing the grating period and possibly also the refractive index where a strain dependence of refractive index is present in the fibre material. Other types of thermal-based, strain-based or other actuator may be used also. The action of the actuators is to modify the grating spectral response and phase, and thereby alter the output coupling mode of the SSFBG cavity, to change the width, rate, shape and/or amplitude of the output pulses. In the illustrated example, eight actuators 67 are shown, four on either side of the phase shift 14, but this is not limiting, and more or fewer actuators 67 may be used, including just one, depending on the resolution desired for the modification of the SSFBG grating. Similarly, different numbers of actuators 67 may be provided on each side of the phase shift 14; this may be more convenient where the phase shift 14 is displaced from the centre of the SSFBG, for example. Overall, the effect of the perturbations can be to alter the local effective grating period of the Bragg grating, and/or to alter the Brillouin acoustic grating. Hence the laser operation can be controlled by modification of the grating forming the cavity, or by modification of the strength of the Brillouin gain. Regarding this latter, varied strain and temperature along a fibre is known to reduce Brillouin gain. By local adjustment, for example over a central part of the SSFBG where the Raman optical field is greatest, the Brillouin gain can be reduced with minimal effect on the Raman gain.

The processor may utilise an algorithm to determine appropriate control signals in response to the output pulse measurement. An algorithm or alternative approach to control signal generation can be derived and/or developed or evolved using artificial intelligence and/or machine learning. In other examples, the control signals may be generated other than in response to the output pulse measurement. For example, they might follow a timed sequence in order to produce a time-varying pulsed output from the optical source, or may respond to environmental factors.

The various embodiments described herein are presented only to assist in understanding and teaching the claimed features. These embodiments are provided as a representative sample of embodiments only, and are not exhaustive and/or exclusive. It is to be understood that advantages, embodiments, examples, functions, features, structures, and/or other aspects described herein are not to be considered limitations on the scope of the invention as defined by the claims or limitations on equivalents to the claims, and that other embodiments may be utilised and modifications may be made without departing from the scope of the claimed invention. Various embodiments of the invention may suitably comprise, consist of, or consist essentially of, appropriate combinations of the disclosed elements, components, features, parts, steps, means, etc., other than those specifically described herein. In addition, this disclosure may include other inventions not presently claimed, but which may be claimed in the future.

### REFERENCES

[1] Y. Hu and N. G. R. Broderick, “Improved design of a DFB Raman fibre laser,” Optics communications, vol. 282, no. 16, pp. 3356-3359, 2009.
[2] P. S. Westbrook, K. S. Abedin, J. W. Nicholson, T. Kremp and J. Porque, “Raman fiber distributed feedback lasers,” Optics Letters, vol. 36, no. 15, pp. 2895-2897, 2011.
[3] J. Shi, S.-u. Alam and M. Ibsen, “Sub-watt threshold, kilohertz-linewidth Raman distributed-feedback fiber laser,” Optics Letters, vol. 37, no. 9, pp. 15544-1546, 2012.
[4] S. Loranger, V. Karpov, G. W. Schinn and R. Kashyap, “Single-frequency low-threshold linearly polarized DFB Raman fiber lasers,” Optics Letters, vol. 42, no. 19, pp. 3864-3867, 2017.
[5] F. L. Galeener, J. C. Mikkelsen Jr, R. Geils and W. J. Mosby, “The relative Raman cross sections of vitreous SiO2, GeO2, B2O3, and P2O5”, Applied Physics Letters, 32(1), pp. 34-36, 1978
[6] S. Loranger, A. Tehranchi, H. Winful and R. Kashyap, “Realization and optimization of phase-shifted distributed feedback fibre Bragg grating Raman lasers”, Optica, 5(3), pp. 295-302, 2018

1. An optical source comprising:
a pump source operable to generate laser light at a first wavelength;
a single mode optical fibre arranged to receive laser light at the first wavelength from the pump source, the optical fibre being fabricated from material having a Raman gain profile for stimulated Raman scattering of light at the first wavelength such that received laser light at the first wavelength experiences stimulated Raman scattering within the optical fibre to a second wavelength longer than the first wavelength, and a Brillouin gain profile for stimulated Brillouin scattering of light at the second wavelength to a third wavelength longer than the second wavelength; and
a superstructured fibre Bragg grating formed in the optical fibre, the grating comprising:
a periodic refractive index profile along a core of the optical fibre, giving transmission of the first wavelength to allow received laser light at the first wavelength to enter the superstructured fibre Bragg grating, reflection of the second wavelength at a first level, and reflection of the third wavelength at a second level lower than the first level; and
a phase shift at an intermediate location along a length of the grating to create, via the reflection at the first level, a resonant cavity for the second wavelength that enables light at the second wavelength to reach an intracavity power sufficient for the stimulated Brillouin scattering to occur so that light at the second wavelength undergoes a wavelength shift to the third wavelength until the intracavity power at the second wavelength becomes insufficient for the stimulated Brillouin scattering to occur, the light at the third wavelength coupling out of the resonant cavity, via the reflection at the second level, as a series of pulses corresponding to the intracavity power at the second wavelength being sufficient for the stimulated Brillouin scattering to occur;
wherein the series of pulses at the third wavelength comprises a pulsed output of the optical source.

2. An optical source according to claim 1, wherein the reflection at the first level provides a resonant cavity for the second wavelength with a finesse of about 250 or above.

3. An optical source according to claim 1, wherein the reflection at the first level is at least 20 dB greater than the reflection at the second level.

4. An optical source according to claim 1, where in the phase shift is in the range of pi/2 to pi.

5. An optical source according to claim 1, wherein the intermediate location of the phase shift is substantially a central point of the length of the grating.

6. An optical source according to claim 1, wherein the intermediate location of the phase shift is closer to one end of the grating.

7. An optical source according to claim 1, wherein the a periodic refractive index profile of the grating is apodised at one or both ends.

8. An optical source according to claim 1, wherein the material from which the optical fibre is fabricated comprises silica.

9. An optical source according to claim 8, wherein the silica comprises one or more dopants.

10. An optical source according to claim 9, wherein the one or more dopants comprise germanium, phosphorus, boron, aluminium, fluorine or bismuth.

11. An optical source according to claim 1, wherein the single mode optical fibre has a core with a width in the range of 1.5 μm to 10 μm.

12. An optical source according to claim 1, wherein the pump source is operable to generate continuous wave laser light at the first wavelength.

13. An optical source according to claim 1, wherein the pump source is operable to generate pulses of laser light at the first wavelength, with a pulse repetition rate, to drive the pulsed output of the optical source at the same repetition rate.

14. An optical source according to claim 1, wherein the pump source comprises a semiconductor diode laser.

15. An optical source according to claim 14, further comprising a stabilisation fibre Bragg grating arranged on an opposite side of the superstructured fibre Bragg grating from the semiconductor diode laser, and configured to be reflective at the first wavelength in order to provide stabilising optical feedback to the semiconductor diode laser.

16. An optical source according to claim 1, wherein the pump source comprises a pump resonant cavity for light at the first wavelength defined by a pair of fibre Bragg gratings reflective at the first wavelength and formed in optical fibre around a portion of optical fibre configured to provide optical gain at the first wavelength, the superstructured fibre Bragg grating being located within the pump resonant cavity.

17. An optical source according to claim 1, wherein the periodic refractive index profile of the superstructured fibre Bragg grating is further configured to provide reflection at a level higher than the second level of one or more additional wavelengths successively shifted from the second wavelength by stimulated Raman scattering to create a resonant cavity at each of the one or more additional wavelengths, light at the third wavelength being obtained by stimulated Brillouin scattering of light at a longest of the one or more additional wavelengths.

18. An optical source according to claim 1, further comprising:
one or more electrical actuators associated with the superstructured fibre Bragg grating, and operable to locally perturb the superstructured fibre Bragg grating to change the reflection at either or both of the second wavelength and third wavelength and thereby modify the pulsed output of the optical source; and
a controller configured to generate and supply separate electrical control signals for each of the one or more electrical actuators in order to produce a required modification of the pulsed output.

19. An optical source according to claim 18, further comprising an optical detector arranged to detect a portion of the pulsed output, generate an electrical signal representing the pulsed output and supply the electrical signal to the controller, wherein the controller is further configured to generate the electrical control signals for the one or more electrical actuators in response to characteristics of the electrical signal from the optical detector.

20. An optical source according to claim 18, wherein the one or more electrical actuators comprise one or more heating elements configured to deliver heat energy to the superstructured fibre Bragg grating.

21. An optical source according to claim 18, wherein the one or more electrical actuators comprise one or more piezo-electric elements configured to apply strain to the superstructured fibre Bragg grating.

22. A method for generating optical pulses, comprising:
delivering pump laser light at a first wavelength into a resonant cavity, where the resonant cavity is formed in single mode optical fibre fabricated from material having a Raman gain profile for stimulated Raman scattering of the pump laser light at the first wavelength such that the delivered pump laser light at the first wavelength experiences stimulated Raman scattering within the optical fibre to a second wavelength longer than the first wavelength, and having a Brillouin gain profile for stimulated Brillouin scattering of light at the second wavelength to a third wavelength longer than the second wavelength;
wherein the resonant cavity comprises a superstructured fibre Bragg grating comprising:
a periodic refractive index profile along a core of the single mode optical fibre, giving transmission of the first wavelength to allow the pump laser light at the first wavelength to enter the superstructured fibre Bragg grating, reflection of the second wavelength at a first level, and reflection of the third wavelength at a second level lower than the first level; and
a phase shift at an intermediate location along a length of the grating to create, via the reflection at the first level, the resonant cavity for resonance of the second wavelength that enables light at the second wavelength to reach an intracavity power sufficient for the stimulated Brillouin scattering to occur so that light at the second wavelength undergoes a wavelength shift to the third wavelength until the intracavity power at the second wavelength becomes insufficient for the stimulated Brillouin scattering to occur, the light at the third wavelength coupling out of the resonant cavity, via the reflection at the second level, as a series of pulses corresponding to the intracavity power at the second wavelength being sufficient for the stimulated Brillouin scattering to occur; and
taking the series of pulses at the third wavelength as the generated optical pulses.

23. A method according to claim 22, further comprising generating electrical control signals for one or more electrical actuators associated with the superstructured fibre Bragg grating, and supplying a separate control signal to each of the one or more electrical actuators to operate the one or more electrical actuators to locally perturb the superstructured fibre Bragg grating to change reflection at either or both of the second wavelength and the third wavelength and thereby modify the generated optical pulses.

24. A method according to claim 23, further comprising detecting a portion of the generated optical pulses to generate an electrical signal representing the optical pulses, and generating the electrical control signals for the one or more electrical actuators in response to characteristics of the electrical signal.
